(19) United States
(12) Patent Application Publication
(10) Pub. No.: US 2026/0323827 A1
(43) Pub. Date: Oct. 15, 2026

(54) PRINTED CIRCUIT BOARD

(71) Applicant: SAMSUNG ELECTRO-MECHANICS CO., LTD., Suwon-si (KR)

(72) Inventors: Tae Hee Yoo, Suwon-si (KR); Jong Eun Park, Suwon-si (KR)

(73) Assignee: SAMSUNG ELECTRO-MECHANICS CO., LTD., Suwon-si (KR)

(21) Appl. No.: 19/715,721

(22) Filed: Jun. 22, 2026

Related U.S. Application Data
(63) Continuation of application No. 19/088,264, filed on Mar. 24, 2025.

(30) Foreign Application Priority Data
Dec. 3, 2024 (KR) 10-2024-0177248

(51) Int. Cl. H05K 1/11; H05K 1/02; H05K 1/03

(52) U.S. Cl. CPC H05K 1/115; H05K 1/0298; H05K 1/0306; H05K 2201/096; H05K 2201/09827

(57) ABSTRACT

The present disclosure relates to a printed circuit board including: a glass layer; a metal via penetrating through at least a portion between an upper surface and a lower surface of the glass layer; a first insulating layer disposed on the upper surface of the glass layer; a second insulating layer disposed on an upper surface of the first insulating layer and including an insulating material different from the first insulating layer; a first wiring layer disposed on an upper surface of the second insulating layer; and a first connection via penetrating through the first and second insulating layers together and connecting at least a portion of the first wiring layer to an upper surface of the metal via.

### CROSS-REFERENCE TO RELATED APPLICATION(S)

This application is the continuation application of U.S. Patent Application No. 19/088,264 filed on Mar. 24, 2025, which claims benefit of priority to Korean Patent Application No. 10-2024-0177248 filed on Dec. 3, 2024, in the Korean Intellectual Property Office, the disclosures of which are incorporated herein by reference in their entirety.

### TECHNICAL FIELD

The present disclosure relates to a printed circuit board.

In order to respond to the high-performance and miniaturization strategies of semiconductors, the level of miniaturization and high-density required for printed circuit boards has increased. For example, in order to manufacture high-end products such as server boards, high-layer and large bodies are required. However, as the number of wiring layers increases and the body size increases, the board may become vulnerable to warpage. To solve this problem, the use of a glass core is being considered. However, since the surface of the glass may be smooth, the adhesion with the insulating material may be low, and therefore voids or delamination may occur.

### SUMMARY

An aspect of the present disclosure is to provide a printed circuit board that may improve the adhesion between a glass layer and an insulating layer and may improve voids and delamination.

One of the various solutions of the present disclosure is to stack first and second insulating layers including different insulating materials on a glass layer and to form a connection via penetrating through the first and second insulating layers together. In this case, a side surface of the connection via may have a protrusion portion or a step portion inside the first and second insulating layers, for example, near a boundary between the first and second insulating layers.

For example, a printed circuit board according to an example embodiment may include: a glass layer; a metal via penetrating through at least a portion between an upper surface and a lower surface of the glass layer; a first insulating layer disposed on the upper surface of the glass layer; a second insulating layer disposed on an upper surface of the first insulating layer and including an insulating material different from the first insulating layer; a first wiring layer disposed on an upper surface of the second insulating layer; and a first connection via penetrating through the first and second insulating layers together and connecting at least a portion of the first wiring layer to an upper surface of the metal via.

For example, a printed circuit board according to an example embodiment may include: a glass layer; a metal via penetrating through at least a portion of the glass layer; an insulating layer disposed on the glass layer; a wiring layer disposed on the insulating layer; and a connection via penetrating through the insulating layer and connecting at least a portion of the wiring layer to the metal via. A side surface of the connection via may have a protrusion portion or a step portion, and the protrusion portion or the step portion may be disposed inside the insulating layer.

One of the various effects of the present disclosure is to provide a printed circuit board that may improve the adhesion between a glass layer and an insulating layer and may improve voids and delamination.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a cross-sectional view schematically illustrating an example of a printed circuit board;

FIG. 3 is a process diagram schematically illustrating an example of manufacturing an enlarged portion of the printed circuit board of FIG. 2;

FIG. 4 is a cross-sectional view schematically illustrating another example of a printed circuit board; and

FIGS. 5 and 6 are cross-sectional views schematically illustrating another example of a printed circuit board, respectively.

### DETAILED DESCRIPTION

Hereinafter, the present disclosure will be described with reference to the accompanying drawings. In the drawings, the shape and size of the elements may be exaggerated or reduced for clearer description.

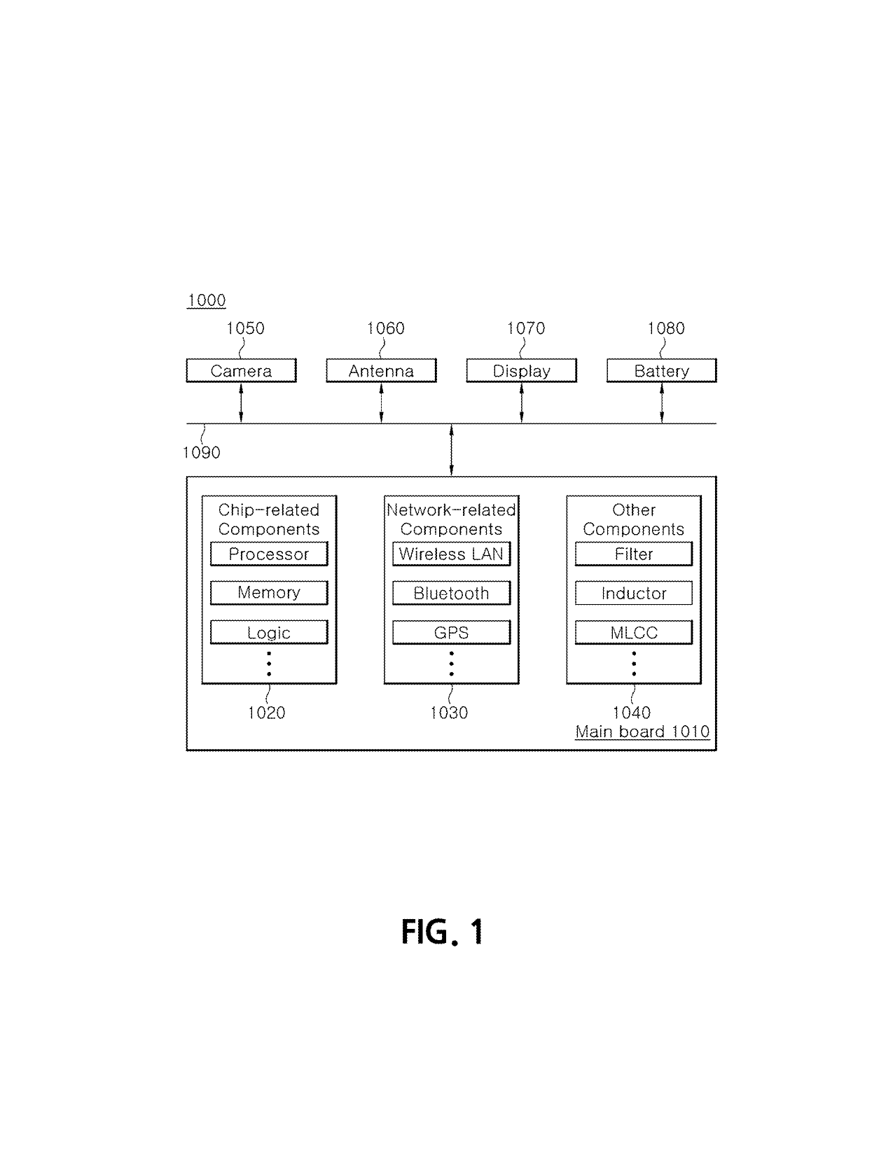

FIG. 1 is a block diagram schematically illustrating an example of an electronic device system.

Referring to FIG. 1, an electronic device 1000 accommodates a main board 1010 therein. Chip-related components 1020, network-related components 1030, and other components 1040, and the like, are physically and/or electrically connected to the main board 1010. These components are also coupled to other electronic components to be described below to form various signal lines 1090.

The chip-related components 1020 may include a memory chip such as a volatile memory (e.g., a DRAM), a non-volatile memory (e.g., a ROM), a flash memory, or the like; an application processor chip such as a central processor (e.g., a CPU), a graphics processor (e.g., a GPU), a digital signal processor, a cryptographic processor, a microprocessor, a microcontroller, or the like; and a logic chip such as an analog-to-digital (ADC) converter, an application-specific IC (ASIC), or the like. However, the chip-related components 1020 are not limited thereto, and may also include other types of chip-related electronic components. Furthermore, the chip-related components 1020 may be coupled to each other. The chip-related component 1020 may have the form of a package including the above-described chip or electronic component.

The network-related components 1030 may include wireless fidelity (Wi-Fi) (such as IEEE 802.11 family), worldwide interoperability for microwave access (WiMAX) (such as IEEE 802.16 family), IEEE 802.20, long term evolution (LTE), evolution data only (Ev-DO), HSPA+, HSDPA+, HSUPA+, EDGE, GSM, GPS, GPRS, CDMA, TDMA, DECT, Bluetooth, 3G, 4G, and 5G protocols, and any other wireless and wired standards or protocols specified thereafter. However, the network-related components 1030 are not limited thereto, and may also include any of a number of other wireless or wired standards or protocols. Furthermore, the network-related components 1030 may be coupled to the chip-related components 1020.

Other components 1040 may include a high frequency inductor, a ferrite inductor, a power inductor, ferrite beads, a low temperature co-firing ceramic (LTCC), an electromagnetic interference (EMI) filter, a multilayer ceramic capacitor (MLCC), or the like. However, other components are not limited thereto, and may also include passive components in the form of chip components used for various other purposes. Additionally, other components 1040 may be coupled to each other, together with the chip-related components 1020 and/or the network-related components 1030.

Depending on a type of electronic device 1000, the electronic device 1000 may include other electronic components that may or may not be physically and/or electrically connected to main board 1010. These other electronic components may include, for example, a camera module 1050, an antenna module 1060, a display 1070, and a battery 1080. However, these other electronic components are not limited thereto, but may also include an audio codec, a video codec, a power amplifier, a compass, an accelerometer, a gyroscope, a speaker, a mass storage device (e.g., a hard disk drive), a compact disk (CD), a digital versatile disk (DVD), or the like. In addition thereto, other electronic components used for various purposes depending on a type of electronic device 1000 may be included.

The electronic device 1000 may be a smartphone, a personal digital assistant, a digital video camera, a digital still camera, a network system, a computer, a monitor, a tablet PC, a laptop PC, a netbook PC, a television, a video game machine, a smartwatch, an automotive component. However, the electronic device 1000 is not limited thereto, and may be any other electronic device that processes data in addition thereto.

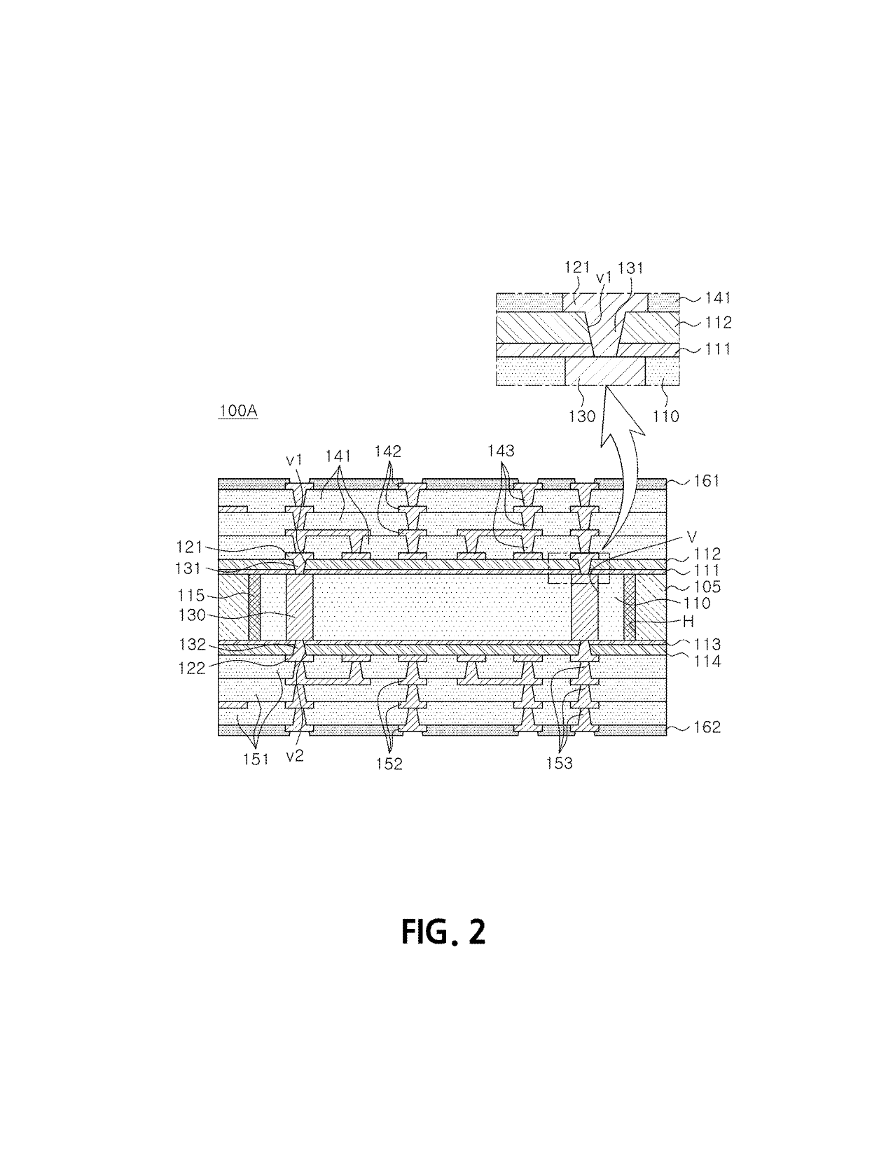

FIG. 2 is a cross-sectional view schematically illustrating an example of a printed circuit board.

Referring to FIG. 2, a printed circuit board 100A according to an example embodiment may include a glass layer 110, a metal via 130 penetrating through at least a portion between an upper surface and a lower surface of the glass layer 110, a first insulating layer 111 disposed on the upper surface of the glass layer 110, a second insulating layer 112 disposed on an upper surface of the first insulating layer 111 and including an insulating material different from the first insulating layer 111, a first wiring layer 121 disposed on an upper surface of the second insulating layer 112, and a first connection via 131 penetrating through the first and second insulating layers 111 and 112 together and connecting at least a portion of the first wiring layer 121 to an upper surface of the metal via 130. For example, the first insulating layer 111 may be an adhesive layer introduced to improve adhesion, and the second insulating layer 112 may be an insulating layer built up to form the first wiring layer 121. Accordingly, the first and second insulating layers 111 and 112 may include different insulating materials and may have distinct boundaries. Additionally, the second insulating layer 112 may be thicker than the first insulating layer 111 on the upper surface of the glass layer 110.

In this manner, in the printed circuit board 100A according to an example embodiment, the first insulating layer 111 that has better adhesion to the glass layer 110 and is relatively thin may be first formed on the glass layer 110, and then, the second insulating layer 112 may be formed on the first insulating layer 111. For example, the first insulating layer 111 may include an insulating material having relatively excellent adhesion to the surface of the glass layer 110. For example, the first insulating layer 111 may include a primer or a bonding sheet. Accordingly, even when an insulating material having relatively low adhesion to the surface of the glass layer 110, such as an Ajinomoto Build up Film (ABF) including an epoxy-based thermosetting polymer resin, is used as the second insulating layer 112, adhesion may be sufficiently secured, and thus problems such as voids or delamination may be effectively improved.

Meanwhile, the printed circuit board 100A according to an example embodiment may further include a third insulating layer 113 disposed on the lower surface of the glass layer 110, a fourth insulating layer 114 disposed on a lower surface of the third insulating layer 113 and including an insulating material different from the third insulating layer 113, a second wiring layer 122 disposed on a lower surface of the fourth insulating layer 114, and a second connection via 132 penetrating the third and fourth insulating layers 113 and 114 together and connecting at least a portion of the second wiring layer 122 to a lower surface of the metal via 130. For example, the third insulating layer 113 may be an adhesive layer introduced to improve adhesion, and the fourth insulating layer 114 may be an insulating layer built up to form the second wiring layer 122. Accordingly, the third and fourth insulating layers 113 and 114 may include different insulating materials and may have distinct boundaries. Additionally, the fourth insulating layer 114 may be thicker than the third insulating layer 113 on the lower surface of the glass layer 110.

In this manner, the printed circuit board 100A according to an example embodiment may have a structure in which the adhesion as described above is secured on the lower surface of the glass layer 110 as needed. Additionally, the first and second connection vias 131 and 132 may be directly connected to the metal via 130, respectively. For example, the first and second connection vias 131 and 132 may be directly connected to the metal via 130 without a pad or a land, so that an overall thickness of the board may be made thinner and the signal transmission path may be reduced. Additionally, the first and second wiring layers 121 and 122 may be formed on the second and fourth insulating layers 112 and 114 instead of the glass layer 110, so that the reliability of the first and second wiring layers 121 and 122 may be improved by improving the adhesion, etc., and more diverse design designs may be possible.

Additionally, the printed circuit board 100A according to an example embodiment may further include a frame 105 having a through-portion H in which at least a portion of the glass layer 110 is disposed, and a filler 115 disposed between the first and third insulating layers 111 and 113 and filling at least a portion between the frame 105 and the glass layer 110 within the through-portion H. The frame 105 may include a material having excellent rigidity. The frame 105 may be used as a jig during a manufacturing process.

In this manner, the printed circuit board 100A according to an example embodiment may further include a frame 105 as needed, and thus may be advantageous for warpage control. Additionally, the frame 105 may be used as a jig as described above, so that the process may be performed on a panel level through the frame 105. In this case, the frame 105 may remain in a final unit after singulation, which may be advantageous for warpage control as described above. Meanwhile, the filler 115 may be formed separately from the first and third insulating layers 111 and 113, and boundaries thereof may be distinguished from each other, but the present disclosure is not limited thereto. For example, if necessary, the filler 115 may be formed while filling the through-portion H when forming at least one of the first and third insulating layers 111 and 113, in which case the filler 115 may be integrated with at least one of the first and third insulating layers 111 and 113 without a boundary.

Additionally, a printed circuit board 100A according to an example embodiment may further include a plurality of first build-up insulating layers 141 disposed on the upper surface of the second insulating layer 112, a plurality of first build-up wiring layers 142 disposed on or within the plurality of first build-up insulating layers 141, and/or a plurality of first build-up via layers 143 respectively disposed within the plurality of first build-up insulating layers 141 and respectively connected to at least one of the plurality of first build-up wiring layers 142. For example, a build-up layer may be further formed on an upper side of the glass layer 110 as needed. For example, the printed circuit board 100A may have a build-up layer formed on at least one side of the glass layer 110 and may be used as a package substrate or an interposer substrate or the like.

Additionally, the printed circuit board 100A according to an example embodiment may further include a plurality of second build-up insulating layers 151 disposed on the lower surface of the fourth insulating layer 114, a plurality of second build-up wiring layers 152 disposed on or within the plurality of second build-up insulating layers 151, and/or a plurality of second build-up via layers 153 respectively disposed within the plurality of second build-up insulating layers 151 and respectively connected to at least one of the plurality of second build-up wiring layers 152. For example, a build-up layer may further be formed on a lower side of the glass layer 110 as needed. For example, the printed circuit board 100A may have build-up layers formed on both sides of the glass layer 110, and may be used as a package substrate or an interposer substrate, or the like.

Additionally, the printed circuit board 100A according to an example embodiment may further include a first passivation layer 161 disposed on the first build-up insulating layer 141 disposed on an uppermost side, among the plurality of first build-up insulating layers 141, and having a first opening covering at least a portion of the first build-up wiring layer 142 disposed on an uppermost side, among the plurality of first build-up wiring layers 142, and exposing at least another portion thereof, and/or a second passivation layer 162 disposed on the second build-up insulating layer 151 disposed on a lowermost side, among the plurality of second build-up insulating layers 151, and having a second opening covering at least a portion of the second build-up wiring layer 152 disposed on a lowermost side, among the plurality of second build-up wiring layers 152, and exposing at least another portion thereof. For example, passivation layers 161 and 162 may be further formed on an outermost side of the printed circuit board 100A as needed. Accordingly, an internal structure of the printed circuit board 100A may be protected more easily.

Hereinafter, components of a printed circuit board 100A according to an example embodiment will be described in more detail with reference to the drawings.

The frame 105 may include an insulating material. The insulating material may include a thermosetting resin such as an epoxy resin, a thermoplastic resin such as a polyimide, or an inorganic filler, an organic filler, and/or glass fiber (Glass Fiber, Glass Cloth or Glass Fabric) along with the resin. For example, the insulating material may include Copper Clad Laminate (CCL) or Unclad CCL, but the present disclosure is not limited thereto, and the insulating material may include other organic or inorganic materials having excellent rigidity. The through-portion H may penetrate between the upper surface and the lower surface of the frame 105. The through-portion H may continuously surround a side surface of the glass layer 110.

The glass layer 110 may include glass, which is an amorphous solid. The glass may include, for example, pure silicon dioxide (about 100% SiO₂), soda-lime glass, borosilicate glass, alumino-silicate glass, etc. However, the present disclosure is not limited thereto, and alternative glass materials, for example, fluorine glass, phosphate glass, chalcogen glass, or the like, may also be used as the material. Additionally, other additives may be further included to form a glass having specific physical properties. These additives may include not only calcium carbonate (e.g., lime) and sodium carbonate (e.g., soda), but also magnesium, calcium, manganese, aluminum, lead, boron, iron, chromium, potassium, sulfur, and antimony, and carbonates and/or oxides of these elements and other elements. Meanwhile, the glass layer 110 may be distinguished from an organic insulating material including glass fiber (Glass Fiber, Glass Cloth or Glass Fabric), for example, Copper Clad Laminate (CCL), Prepreg (PPG), or the like. The glass layer 110 may be, for example, in the form of a glass plate. A through-hole V in which the metal via 130 is disposed may penetrate between the upper surface and the lower surface of the glass layer 110. The glass layer 110 may have a roughly rectangular shape on a plane, but the present disclosure is not limited thereto. For example, the glass layer 110 may have a roughly oval shape on a plane.

Each of the first and third insulating layers 111 and 113 may include an insulating material having a relatively excellent adhesion to the glass layer 110 as compared to the second and fourth insulating layers 112 and 114. For example, each of the first and third insulating layers 111 and 113 may include a primer and a bonding sheet. The primer may be an organic silane primer, an epoxy primer, a polyurethane primer, an acrylic primer, or the like, but is not limited thereto. The bonding sheet may be an epoxy adhesive sheet, a polyimide adhesive sheet, a polyurethane adhesive sheet, an acrylic adhesive sheet, or a silicone adhesive sheet, but is not limited thereto. As described above, each of the first and third insulating layers 111 and 113 may include an insulating material different from the second and fourth insulating layers 112 and 114.

The second and fourth insulating layers 112 and 114 may include an insulating material, more specifically, an organic insulating material. The organic insulating material may include a thermosetting resin such as an epoxy resin, a thermoplastic resin such as a polyimide, or an inorganic filler, an organic filler, and/or glass fiber (Glass Fiber, Glass Cloth or Glass Fabric) along with the resin. For example, the organic insulating material may include Prepreg (PPG) and an Ajinomoto Build-up Film (ABF), but the present disclosure is not limited thereto. As described above, the second and fourth insulating layers 112 and 114 may include different insulation materials from the first and third insulating layers 111 and 113, respectively.

Each of the first and second wiring layers 121 and 122 may include a metal. The metal may include copper (Cu), aluminum (Al), silver (Ag), tin (Sn), gold (Au), nickel (Ni), lead (Pb), titanium (Ti), and/or alloys thereof. For example, each of the first and second wiring layers 121 and 122 may include chemical copper formed by electroless plating as a seed layer, and may include electrolytic copper formed by electrolytic plating as a plating layer based thereon. The first and second wiring layers 121 and 122 may each perform various functions depending on the design. For example, each of the first and second wiring layers 121 and 122 may include a signal pattern, a power pattern and a ground pattern. These patterns may have various shapes, such as a line, a trace, a plane, a land, a pad, and a land, respectively.

The metal via 130 may include a metal. The metal may include copper (Cu), aluminum (Al), silver (Ag), tin (Sn), gold (Au), nickel (Ni), lead (Pb), titanium (Ti), and/or alloys thereof. For example, the metal via 130 may include a titanium layer and a copper layer formed by sputtering, that is, sputtered titanium and sputtered copper, as seed layers, and may include electrolytic copper formed by electrolytic plating as a plating layer based thereon. If necessary, the metal via 130 may further include chemical copper formed by electroless plating on the titanium layer and copper layer formed by sputtering as seed layers. The metal via 130 may perform various functions depending on the design. For example, the metal via 130 may include a through-via for signal transmission, a through-via for power transmission, and a through-via for ground transmission. The metal via 130 may include a filled via in which at least a portion of the through-hole V is filled with a metal. The metal via 130 may have a cylindrical shape, but may also have an hourglass shape. An upper surface and a lower surface of the metal via 130 may be recessed more inwardly than the upper surface and the lower surface of the glass layer 110, respectively, and thus, the upper surface and the lower surface of the metal via 130 may have a step portion from the upper surface and the lower surface of the glass layer 110, respectively, but the present disclosure is not limited thereto. The metal via 130 may be provided in plural.

Each of the first and second connection vias 131 and 132 may include a metal. The metal may include copper (Cu), aluminum (Al), silver (Ag), tin (Sn), gold (Au), nickel (Ni), lead (Pb), titanium (Ti), and/or alloys thereof. For example, each of the first and second connection vias 131 and 132 may include chemical copper formed by electroless plating as a seed layer, and may include electrolytic copper formed by electrolytic plating as a plating layer based on the chemical copper. Each of the first and second connection vias 131 and 132 may perform various functions depending on the design. For example, each of the first and second connection vias 131 and 132 may include a connection via for signal transmission, a connection via for power transmission, and a connection via for ground transmission. The first and second connection vias 131 and 132 may include a filled via in which at least a portion of via holes v1 and v2 are filled with a metal, but may also include a conformal via in which the metal is disposed along wall surfaces of the via holes v1 and v2. The first and second connection vias 131 and 132 may have shapes that are tapered in opposite directions. The first and second connection vias 131 and 132 may be directly connected to the upper surface and the lower surface of the metal vias 130, respectively. For example, the first and second connection vias 131 and 132 may be in direct contact with each other. When there is a plurality of metal vias 130, there may also be a plurality of first and second connection vias 131 and 132 correspondingly.

Each of the plurality of first and second build-up insulating layers 141 and 151 may include an organic insulating material. The organic insulating material may include a thermosetting resin such as an epoxy resin, a thermoplastic resin such as a polyimide, or an inorganic filler, an organic filler, and/or glass fiber (Glass Fiber, Glass Cloth or Glass Fabric) along with the resin. For example, the organic insulating material may include Prepreg (PPG), an Ajinomoto Build-up Film (ABF) and Photoimageable Dielectric (PID), but the present disclosure is not limited thereto. Each of the plurality of first and second build-up insulating layers 141 and 151 may be formed of a plurality of layers. In this case, each of the plurality of layers may be integrated without a boundary, or the boundary between the layers may be identified. Additionally, each of the plurality of layers may include substantially the same insulating material, or may include different insulating materials. The plurality of first and second build-up insulating layers 141 and 151 may have the same number of layers, but the present disclosure is not limited thereto, and the plurality of first build-up insulating layers 141 may have a relatively greater number of layers. If necessary, the plurality of second build-up insulating layers 151 may be omitted.

Each of the first and second build-up wiring layers 142 and 152 may include a metal. The metal may include copper (Cu), aluminum (Al), silver (Ag), tin (Sn), gold (Au), nickel (Ni), lead (Pb), titanium (Ti), and/or alloys thereof. For example, each of the first and second build-up wiring layers 142 and 152 may include chemical copper formed by electroless plating as a seed layer, and may include electrolytic copper formed by electrolytic plating based on the chemical copper as a plating layer. Each of the first and second build-up wiring layers 142 and 152 may perform various functions according to a design. For example, each of the first and second build-up wiring layers 142 and 152 may include a signal pattern, a power pattern, and a ground pattern. Each of the patterns may have various forms such as a line, a trace, a plane, a land, a pad, and a land. The plurality of first and second build-up wiring layers 142 and 152 may have the same number of layers, but the plurality of first build-up wiring layers 142 may have a relatively greater number of layers. When the plurality of second build-up insulating layers 151 are omitted, the plurality of second build-up wiring layers 152 may also be omitted.

Each of the plurality of first and second build-up via layers 143 and 153 may include a metal. The metal may include copper (Cu), aluminum (Al), silver (Ag), tin (Sn), gold (Au), nickel (Ni), lead (Pb), titanium (Ti), and/or alloys thereof. For example, each of the plurality of first and second build-up via layers 143 and 153 may include chemical copper formed by electroless plating as a seed layer, and may include electrolytic copper formed by electrolytic plating as a plating layer based thereon. Each of the plurality of first and second build-up via layers 143 and 153 may perform various functions according to the design. For example, each of the plurality of first and second build-up via layers 143 and 153 may include a connection via for signal transmission, a connection via for power transmission, and a connection via for ground transmission. Each of the plurality of first and second build-up via layers 143 and 153 may include a filled via in which at least a portion of a via hole is filled with a metal, but may also include a conformal via in which the metal is disposed along a wall surface of the via hole. Each of the plurality of first and second build-up via layers 143 and 153 may include a plurality of connection vias. The connection vias included in each of the plurality of first build-up via layers 143 may have a shape that is tapered in an opposite direction to the connection vias included in each of the plurality of second build-up via layers 153. The plurality of first and second build-up via layers 143 and 153 may have the same number of layers, but the plurality of first build-up via layers 143 may have a relatively greater number of layers. When the plurality of second build-up insulating layers 151 are omitted, the plurality of second build-up via layers 153 may also be omitted.

Each of the first and second passivation layers 161 and 162 may include an organic insulating material. The organic insulating material may include a thermosetting resin such as an epoxy resin, a thermoplastic resin such as a polyimide, or a resin together with an inorganic filler and/or an organic filler. For example, the organic insulating material may include an Ajinomoto Build-up Film (ABF), Photoimageable Dielectric (PID), Solder Resist (SR), but the present disclosure is not limited thereto. Each of the first and second passivation layers 161 and 162 may be formed of a plurality layers. Each of the first and second passivation layers 161 and 162 may have a plurality of openings, and a pattern exposed through each of the openings may be a Solder Mask Defined (SMD) type and/or a Non Solder Mask Defined (NSMD) type, but the present disclosure is not limited thereto.

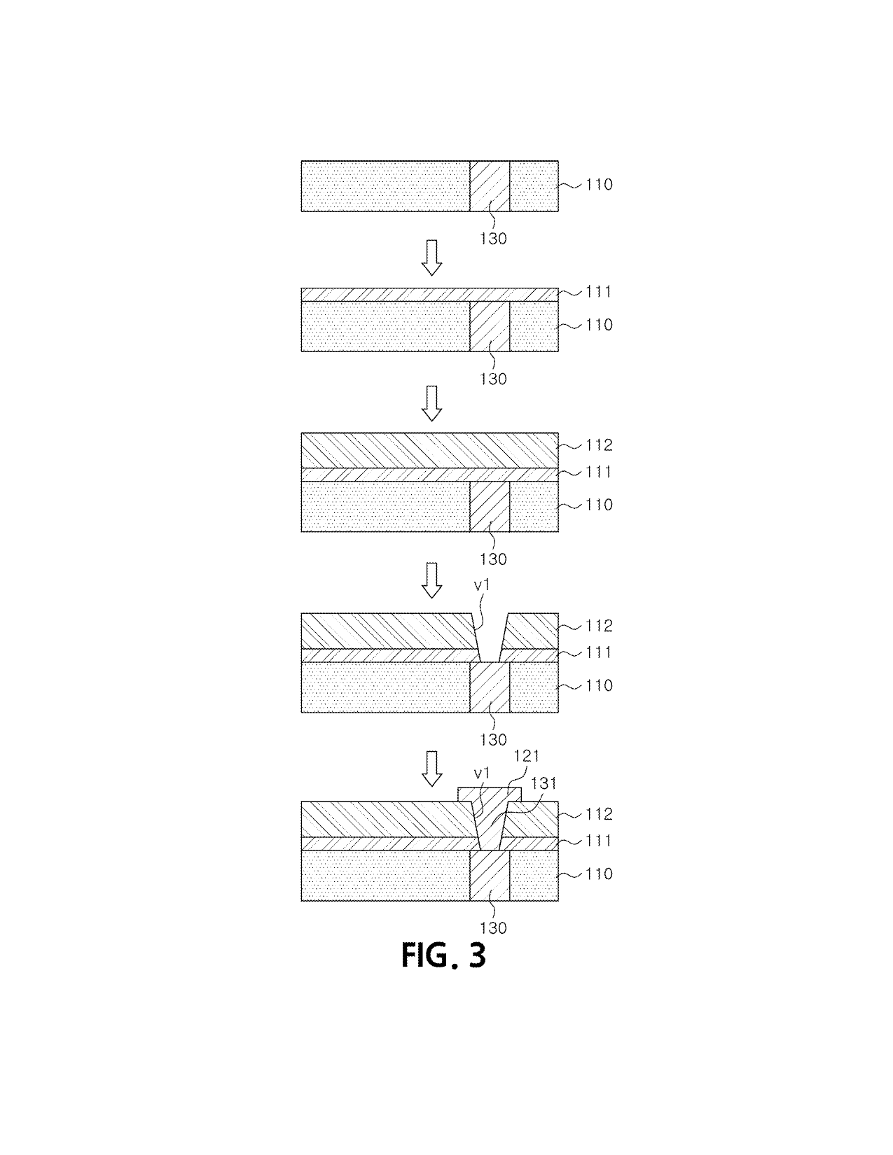

FIG. 3 is a process diagram schematically illustrating an example of manufacturing an enlarged portion of the printed circuit board of FIG. 2.

Referring to FIG. 3, first, a metal via 130 may be formed on the glass layer 110. For example, a through-hole V penetrating through the glass layer 110 may be formed using laser ablation, ultrasonic drilling, dry etching, wet etching, or the like, and then, at least a portion of the through-hole V may be filled with a metal in a fill plating process using sputtering, electroless plating, and/or electrolytic plating, thereby forming the metal via 130. Next, a first insulating layer 111 may be formed on the glass layer 110. For example, the first insulating layer 111 may be formed by coating or stacking a primer or a bonding sheet material on the glass layer 110. The first insulating layer 111 may be a layer for reinforcing adhesion, and may thus be formed relatively thinner than the second insulating layer 112. Next, a second insulating layer 112 may be formed on the first insulating layer 111. For example, the second insulating layer 112 may be formed in a method of stacking an insulating material different from the first insulating layer 111, such as a build-up film, on the first insulating layer 111. The second insulating layer 112 may be a layer for build-up, and may thus be formed to be relatively thicker than the first insulating layer 111. Next, a via hole v1 penetrating through the first and second insulating layers 111 and 112 together and exposing at least a portion of the metal via 130 may be formed. The via hole v1 may be formed by laser processing such as CO₂ laser processing or UV laser processing. Next, a first connection via 131 filling at least a portion of the via hole v1 may be formed. Additionally, a first wiring layer 121 may be formed on the second insulating layer 112. The first connection via 131 and the first wiring layer 121 may be formed by a plating process using electroless plating and/or electrolytic plating. Through a series of processes, the first and second insulating layers 111 and 112, the first connection via 131, and the first wiring layer 121 may be formed on an upper side of the glass layer 110. Substantially the same process as described above may be performed on a lower side of the glass layer 110, and as a result, the third and fourth insulating layers 113 and 114, the second connection via 132, and the second wiring layer 122 may be formed on the lower side of the glass layer 110. The contents described above may be substantially equally applied to the printed circuit board 100A according to the above-described example embodiment.

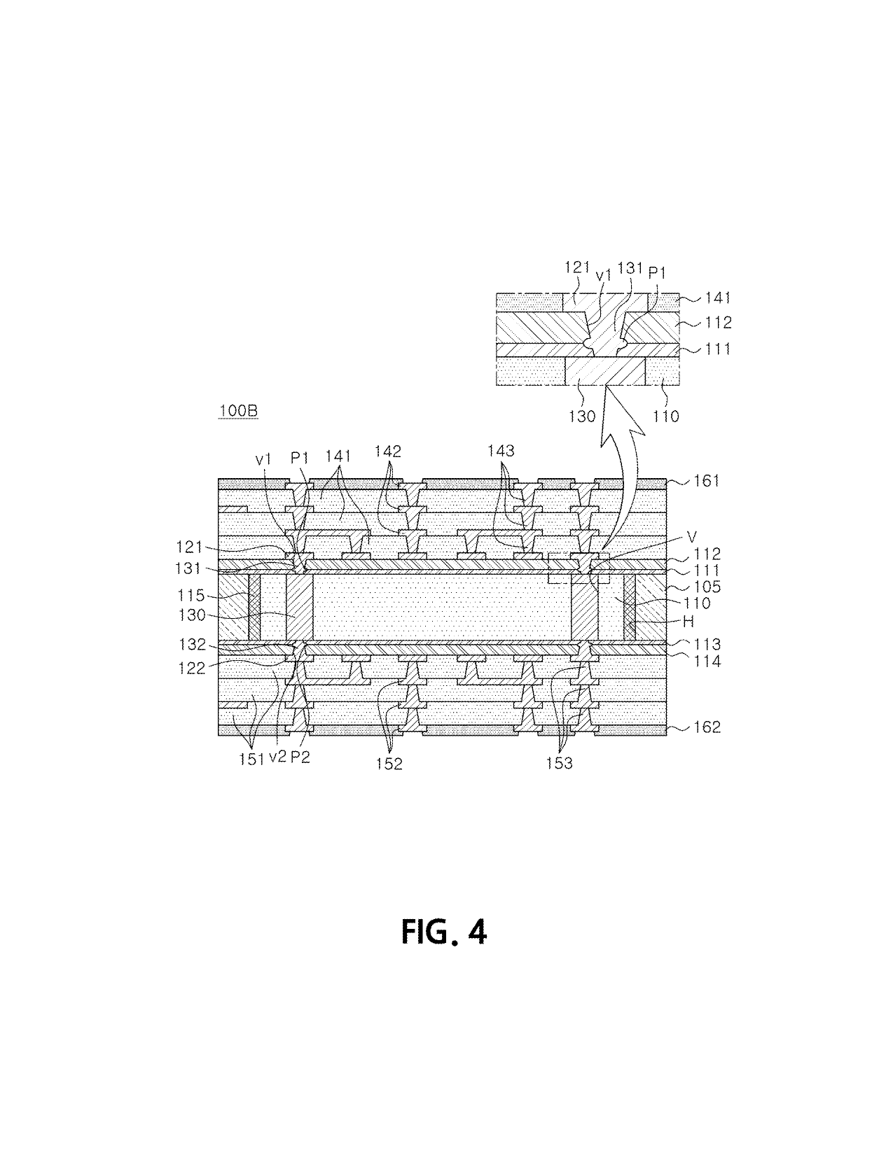

FIG. 4 is a cross-sectional view schematically illustrating another example of a printed circuit board.

Referring to FIG. 4, a printed circuit board 100B according to another example embodiment may be configured so that in the printed circuit board 100A according to the above-described example embodiment, a side surface of the first connection via 131 may have a protrusion portion P1, and in this case, the protrusion portion P1 may be disposed adjacently to a boundary of the first and second insulating layers 111 and 112. Additionally, a thickness of the protrusion portion P1 may become substantially thinner as the protrusion portion P1 moves farther from a side surface of the first connection via 131. For example, in laser processing for forming a via hole v1, when heat from a light source accumulates in the boundary of the first and second insulating layers 111 and 112 including different materials, the heat may spread into a gap between boundary surfaces. In this case, the processability may increase more than other regions due to the accumulated heat centered on the boundary surface, and as a result, a space in a concave shape may be formed along the boundary surface. When the metal is filled in the space, the protrusion portion P1 as described above may be formed. In this manner, when the protrusion portion P1 is formed on the side surface of the first connection via 131, the adhesion between the first connection via 131 and the first and second insulating layers 111 and 112 may be improved, and the reliability may be further improved.

Meanwhile, the second connection via 132 may also have a protrusion portion P2 on a side surface thereof, and in this case, the protrusion portion P2 may be disposed adjacently to the boundary of the third and fourth insulating layers 113 and 114. Additionally, the thickness of the protrusion portion P2 may become substantially thinner as the protrusion portion P2 moves farther from a side surface of a third connection via 133. For example, in laser processing for forming the via hole v2, heat accumulation and diffusion by a light source as described above may occur at the boundary surface of the third and fourth insulating layers 113 and 114 including different materials, and as a result, a space in a concave shape may be formed along the boundary surface of the third and fourth insulating layers 113 and 114, and the metal may be filled in the space, thus forming the protrusion portion P2 described above. When the protrusion portion P2 is formed on a side surface of the second connection via 132, the adhesion between the second connection via 132 and the third and fourth insulating layers 113 and 114 may be improved, and the reliability may be further improved.

Other descriptions may be substantially the same as those described in the printed circuit board 100A according to the above-described example embodiment. Additionally, the above-described manufacturing example embodiment may also be applied in substantially the same manner except for the processing shape of the via.

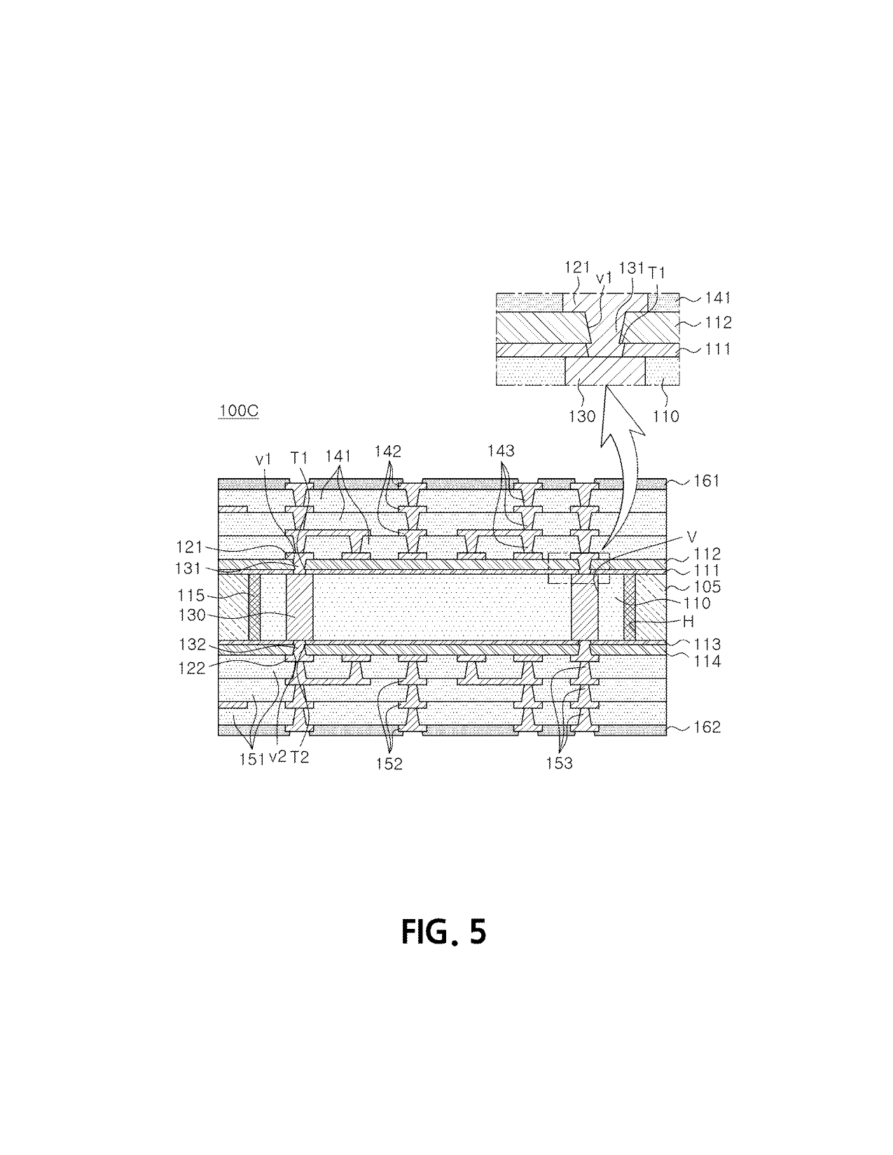

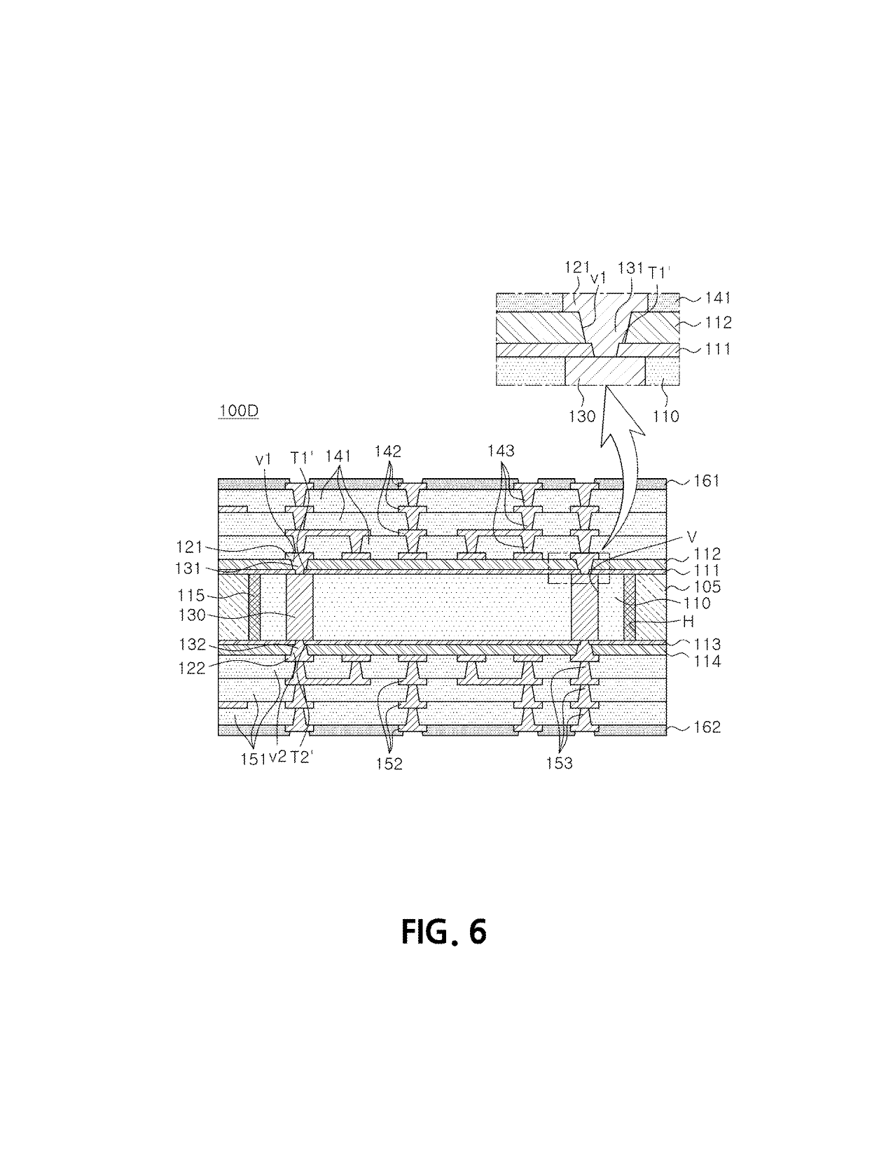

FIGS. 5 and 6 are cross-sectional views schematically illustrating another example of a printed circuit board, respectively.

Referring to the drawings, printed circuit boards 100C and 100D according to another example embodiment may be configured so that in the printed circuit board 100A according to the above-described example embodiment, each side surface of the first connection via 131 may have step portions T1 and T1', and in this case, the step portions T1 and T1' may be disposed adjacently to the boundary of the first and second insulating layers 111 and 112. Additionally, each first connection via 131 may include a first region penetrating through the first insulating layer 111 and a second region penetrating through the second insulating layer 112, and the side surface of the first connection via 131 in the first region and the side surface of the first connection via 131 in the second region may be connected to each other through the step portions T1 and T1'. For example, depending on the type or composition of the material used in the first and second insulating layers 111 and 112 including different materials, there may be differences in an absorption rate, transmittance, reflectivity, and the like, for a laser light source, and as a result, aspects or degrees of heat generation within the first and second insulating layers 111 and 112 may be different from each other. Meanwhile, the laser absorption rate may vary depending on the wavelength or power of the laser, the degree of thermal diffusion of the material, or the like, and the thermal diffusivity of the material may be related to the thermal conductivity and heat capacity, which are characteristics of the material, and the density of the material. Accordingly, even with the same heat source, the size or expansion amount of the via formed in each of the first and second insulating layers 111 and 112 may differ depending on the difference in the thermal properties of the material, and as a result, the via may be formed discontinuously in the boundary of the first and second insulating layers 111 and 112. For example, an external wall of the via may have a stepwise structure. For example, as in the printed circuit board 100C according to another example embodiment, when the amount of expansion due to processing heat in the first insulating layer 111 is greater than that in the second insulating layer 112, a width of the first connection via 131 on the cross-section on an uppermost side of the first region may be wider than a width of the first connection via 131 on the cross-section on a lowermost side of the second region. Also, as in the printed circuit board 100D according to another example embodiment, when the amount of expansion due to processing heat in the second insulating layer 112 is greater than that in the first insulating layer 111, a width of the first connection via 131 on the cross-section on the uppermost side of the first region may be narrower than a width of the first connection via 131 on the cross-section on the lowermost side of the second region. Meanwhile, the printed circuit boards 100C and 100D according to another example embodiment may be configured so that in the printed circuit board 100A according to the above-described example, each side surface of the second connection via 132 may have step portions T2 and T2', and in this case, the step portions T2 and T2' may be disposed adjacently to the boundary of the third and fourth insulating layers 113 and 114. Additionally, each second connection via 132 may include a third region penetrating through the third insulating layer 113 and a fourth region penetrating through the fourth insulating layer 114, and the side surface of the second connection via 132 in the third region and the side surface of the second connection via 132 in the fourth region may be connected to each other through the step portions T2 and T2'. For example, as described above, there may be differences in the size or expansion amount of the via formed in each of the third and fourth insulating layers 113 and 114 including different materials, and as a result, the via may be formed discontinuously in the boundary of the third and fourth insulating layers 113 and 114. For example, an external wall of the via may have a stepwise structure. For example, as in the printed circuit board 100C according to another example embodiment, when the expansion amount due to processing heat in the third insulating layer 113 is greater than that in the fourth insulating layer 114, a width of the second connection via 132 on the cross-section on a lowermost side of the third region may be wider than a width of the second connection via 132 on the cross-section on an uppermost side of the fourth region. Additionally, as in the printed circuit board 100D according to another example embodiment, when the expansion amount due to processing heat in the fourth insulating layer 114 is greater than that in the third insulating layer 113, a width of the second connection via 132 on the cross-section on the lowermost side of the third region may be narrower than a width of the second connection via 132 on the cross-section on the uppermost side of the fourth region.

Other descriptions may be substantially the same as those described in the printed circuit board 100A according to the above-described example embodiment. Additionally, the above-described manufacturing example may also be applied in substantially the same manner except for the processing shape of the via.

In the present disclosure, the expression ‘covering’ may include a case of covering at least a portion as well as a case of covering the whole, and may also include a case of covering not only directly but also indirectly. Furthermore, the expression ‘filling’ may include not only a case of completely filling but also a case of at least partially filling, and may also include a case of approximately filling. For example, this may include a case in which some pores or voids exist. Additionally, the expression ‘surrounding’ may include not only a case of completely surrounding but also a case of partially surrounding and a case of approximately surrounding. Additionally, the expression ‘exposing’ may include not only completely exposing but also partially exposing, and exposing may mean exposing from the filling of the component.

In the present disclosure, being disposing in a through-portion, a through-hole or a via hole may include not only a case in which an object is disposed completely in the through-portion, the through-hole or the via hole, but also a case in which the object protrudes upwardly or downwardly in a cross-section. For example, when the object may be disposed within the through-portion, the through-hole or the via hole on a plane, the object may be determined to be disposed within the through-portion, the through-hole or the via hole in a broader sense.

In the present disclosure, determination may be performed by including process errors, positional deviations, errors at the time of measurement, which may occur in a manufacturing process. For example, substantially the same direction may include not only the completely same direction but also the approximately the same direction. Furthermore, substantially coplanar may include not only the case of being completely coplanar but also the case of being approximately coplanar. Furthermore, substantially having a specific shape may include not only the case of having such a shape completely but also the case of having such a shape approximately. Furthermore, substantially the same insulating material may mean not only the case of being the completely same insulating material but also the case of including the same type of insulating material. Accordingly, the composition of the insulating material may be substantially the same, but the specific composition ratio thereof may be slightly different.

In the present disclosure, the meaning on the cross-section may refer to a cross-sectional shape when an object is cut vertically, or a cross-sectional shape when the object is viewed in a side-view. Furthermore, the meaning on a plane may refer to a planar shape when the object is horizontally cut, or a planar shape when the object is viewed in a top-view or a bottom-view.

In the present disclosure, for convenience, a lower side, a lower portion, and a lower surface are used to refer to a downward direction with respect to a cross-section of a drawing, and an upper side, an upper portion, and an upper surface are used to refer to an opposite direction thereof. However, this is a definition of direction for the convenience of explanation, and the scope of the claim is not specifically limited by the description of this direction, and the concept of upper/lower may be changed at any time.

In the present disclosure, a meaning of being connected is a concept including not only directly connected but also indirectly connected through an adhesive layer or the like. Additionally, the term electrically connected includes both physically connected and not physically connected. Additionally, expressions such as first and second are used to distinguish one component from another, and do not limit the order and/or importance of the components. In some cases, a first component may be referred to as a second component without departing from the scope of rights, or similarly, the second component may be referred to as the first component.

In the present disclosure, a thickness, a width, a length, a depth, a line width, a gap, a pitch, a separation distance, surface roughness, and the like, may be measured using a scanning microscope, an optical microscope, or the like, based on a cross-section of a printed circuit board that has been polished or cut, respectively. The cut cross-section may be a vertical cross-section or a horizontal cross-section, and each value may be measured based on a required cut cross-section. For example, a width of an upper portion and/or a lower portion of a via may be measured on a cross-section that has been cut along a central axis of the via. In this case, when the value is not constant, the value may be determined as an average value of values measured at five arbitrary points.

The expression ‘example embodiment used in the present disclosure’ does not mean the same embodiment, and is provided to explain different unique characteristics. However, the example embodiments presented above do not preclude being implemented in combination with features of other example embodiments. For example, even if matters described in a particular example embodiment are not described in other example embodiments, they may be understood as explanations related to other example embodiments unless there is an explanation contrary to or contradictory to matters in other example embodiments.

The terms used in the present disclosure are used only to describe an example embodiment and are not intended to limit the present disclosure. In this case, singular expressions include plural expressions unless they are clearly meant differently in the context.

What is claimed is:

1. A printed circuit board, comprising:
a glass layer;
a metal via penetrating through at least a portion between an upper surface and a lower surface of the glass layer;
a frame having a through-portion in which at least a portion of the glass layer is disposed;
a first insulating portion disposed on the upper surface of the glass layer;
a second insulating portion disposed on the lower surface of the glass layer;
a filler disposed between the first and second insulating portions and filling at least a portion between the frame and the glass layer;
a first wiring layer disposed on an upper surface of the first insulating portion;
a first connection via penetrating through the first insulating portion and connecting at least a portion of the first wiring layer to an upper surface of the metal via;
a second wiring layer disposed on a lower surface of the second insulating portion; and
a second connection via penetrating through the second insulating portion and connecting at least a portion of the second wiring layer to a lower surface of the metal via,
wherein each of the first and second connection vias are directly connected to the metal via.

2. The printed circuit board according to claim 1,
wherein a lower surface of the first connection via is in contact with the upper surface of the metal via without a pad, and
an upper surface of the second connection via is in contact with the lower surface of the metal via without a pad.

3. The printed circuit board according to claim 1,
wherein a width of a lower surface of the first connection via in a cross-section is smaller than a width of the upper surface of the metal via in the cross-section, and
a width of an upper surface of the second connection via in the cross-section is smaller than a width of the lower surface of the metal via in the cross-section.

4. The printed circuit board according to claim 1,
wherein the first insulating portion is in contact with at least a portion of the upper surface of the metal via, and
the second insulating portion is in contact with at least a portion of the lower surface of the metal via.

5. The printed circuit board according to claim 1,
wherein the metal via and the first connection via are in contact with each other on a level substantially coplanar with the upper surface of the glass layer, and
the metal via and the second connection via are in contact with each other on a level substantially coplanar with the lower surface of the glass layer.

6. The printed circuit board according to claim 1,
wherein the first connection via has a substantially tapered shape in the cross-section in which a width of an upper portion thereof is greater than a width of a lower portion thereof, and
the second connection via has a substantially tapered shape in the cross-section in which a width of a lower portion thereof is greater than a width of an upper portion thereof.

7. The printed circuit board according to claim 1,
wherein the first insulating portion includes a first insulating layer disposed on the upper surface of the glass layer, and a second insulating layer disposed on an upper surface of the first insulating layer, and
the second insulating layer is thicker than the first insulating layer.

8. The printed circuit board according to claim 1,
wherein the second insulating portion includes a third insulating layer disposed on the lower surface of the glass layer, a fourth insulating layer disposed on a lower surface of the third insulating layer, and
the fourth insulating layer is thicker than the third insulating layer.

9. The printed circuit board according to claim 1, further comprising:
a plurality of first build-up insulating layers disposed on the upper surface of the first insulating portion;
a plurality of first build-up wiring layers respectively disposed on or within the plurality of first build-up insulating layers;
a plurality of first build-up via layers respectively disposed within the plurality of first build-up insulating layers and respectively connected to at least one of the plurality of first build-up wiring layers;
a plurality of second build-up insulating layers disposed on the lower surface of the second insulating portion;
a plurality of second build-up wiring layers respectively disposed on or within the plurality of second build-up insulating layers; and
a plurality of second build-up via layers respectively disposed within the plurality of second build-up insulating layers, and respectively connected to at least one of the plurality of second build-up wiring layers.

10. The printed circuit board according to claim 9,
wherein at least a portion of at least one of the first build-up wiring layers is disposed to overlap the frame in a stacking direction.

11. The printed circuit board according to claim 9,
wherein the plurality of first build-up via layers include first stacked vias disposed on the metal via in a stacking direction and connected to the first connection via.

12. The printed circuit board according to claim 11,
wherein the plurality of second build-up via layers include second stacked vias disposed on the metal via in a stacking direction and connected to the second connection via.

13. The printed circuit board according to claim 12,
wherein the first stacked vias are disposed in all layers of the first build-up insulating layers, and
the second stacked vias are disposed in all layers of the second build-up insulating layers.

14. The printed circuit board according to claim 12,
wherein the first stacked vias, the first connection via, the metal via, the second connection via, and the second stacked vias are overlapping each other in the stacking direction.

15. The printed circuit board according to claim 9, further comprising:
a first solder resist layer disposed on an upper surface of a first build-up insulating layer disposed on an uppermost side, among the plurality of first build-up insulating layers, and having a plurality of first openings respectively exposing at least a portion of the first build-up wiring layer disposed on an uppermost side, among the plurality of first build-up wiring layers; and
a second solder resist layer disposed on a lower surface of a second build-up insulating layer, among the plurality of second build-up insulating layers, and having a plurality of second openings respectively exposing at least a portion of a second build-up wiring layer disposed on a lowermost side, among the plurality of second build-up wiring layers.

16. The printed circuit board according to claim 1,
wherein no metal pattern is in contact with the upper and lower surfaces of the glass layer.

17. The printed circuit board according to claim 1,
wherein no metal layer is disposed on upper and lower surfaces of the frame.

18. The printed circuit board according to claim 1,
wherein the frame includes a copper clad laminate.
